(19) United States
(12) Patent Application Publication
(10) Pub. No.: US 2018/0050483 A1
(43) Pub. Date: Feb. 22, 2018

(54) Imprinting Device and Imprinting Method Using the Same

(71) Applicant: BOE TECHNOLOGY GROUP CO., LTD., Beijing (CN)

(72) Inventors: Feng GUAN, Beijing (CN); Jikai YAO, Beijing (CN); Xiaolong HE, Beijing (CN); Hua HUANG, Beijing (CN)

(21) Appl. No.: 15/680,614

(22) Filed: Aug. 18, 2017

(30) Foreign Application Priority Data
Aug. 19, 2016 (CN) 201620695190.2

(51) Int. Cl. B29C 59/02; G03F 7/00

(52) U.S. Cl. CPC B29C 59/02; B29C 59/026; B29C 59/022; G03F 7/0002

(57) ABSTRACT

An imprinting device and an imprinting method using the same are disclosed. The imprinting device includes: a chamber body and a base, which are able to combine with each other to form an imprinting chamber, the imprinting chamber being divided into a first chamber and a second chamber by a dividing film; and a movable supporting member, configured to support an imprinting stencil inside the second chamber, and to allow the imprinting stencil to: under the drive of gas pressure within the imprinting chamber, contact a substrate to be imprinted and apply a pressure to the substrate. The imprinting technical provided by the present disclosure decreases bubble defect rate, improves uniformity of large area imprinting, and makes possible large area nano-imprinting technology.

### TECHNICAL FIELD

The present application relates to the field of display technology, and in particular relates to an imprinting device and an imprinting method using the same.

### BACKGROUND

As the development of semiconductor industry, semiconductor devices are being scaled down to smaller sizes, with manufacturing cost thereof growing exponentially. Imprinting technology such as nano-imprint lithography is a low-cost graphics transfer technology in which a stencil having a pattern is pressed onto a substrate using a mechanical force (generated by high temperature, high pressure and the like) to copy the pattern. Imprinting technology greatly reduces cost by avoiding the use of an expensive light source and a projection optical system.

However, bubble defects exist in products manufactured using the existing imprinting technology. Further, large-area imprinting is generally limited in uniformity.

### SUMMARY

The present disclosure provides an imprinting device and an imprinting method capable of at least partly solving at least one of the problems existing in the prior-art imprinting technology.

According to an aspect of the present disclosure, an imprinting device includes: chamber body and a base, which are able to combine with each other to form an imprinting chamber, the imprinting chamber being divided into a first chamber and a second chamber by a dividing film; and a movable supporting member, configured to support an imprinting stencil inside the second chamber, and to allow the imprinting stencil to: under the drive of gas pressure within the imprinting chamber, contact a substrate to be imprinted and apply a pressure to the substrate to be imprinted.

In an embodiment of the present disclosure, the dividing film may be configured to recess downwardly in a case where gas pressure of the first chamber is higher than gas pressure of the second chamber.

In an embodiment of the present disclosure, the dividing film may be configured to bulge upwardly in a case where gas pressure of the first chamber is lower than gas pressure of the second chamber.

In an embodiment of the present disclosure, the first chamber may be located above the second chamber, the substrate to be imprinted may be placed in the second chamber, and the imprinting stencil may be located between the dividing film and the substrate to be imprinted.

In an embodiment of the present disclosure, the second chamber may be configured to be capable of being vacuumized.

In an embodiment of the present disclosure, the substrate to be imprinted may be placed on the base, the movable supporting member may include a plurality of lifters provided on the base, the lifters may be arranged in peripheral regions of the substrate to be imprinted, and the imprinting stencil may be connected to the lifters via one or more elastic parts.

In an embodiment of the present disclosure, the chamber body and the base may be able to combine with each other via one or more sealing members.

In an embodiment of the present disclosure, the dividing film may include a transparent organic material.

According to another aspect of the present disclosure, in an imprinting method using an imprinting device, the imprinting device includes: a chamber body and a base, which are able to combine with each other to form an imprinting chamber, the imprinting chamber being divided into a first chamber and a second chamber by a dividing film; and a movable supporting member, configured to support an imprinting stencil inside the second chamber, the imprinting method comprising: a step of causing gas pressure within the imprinting chamber to drive the imprinting stencil, such that the imprinting stencil contacts a substrate to be imprinted and applies a pressure to the substrate to be imprinted.

In an embodiment of the present disclosure, the step of causing gas pressure within the imprinting chamber to drive the imprinting stencil may include: causing gas pressure of the first chamber to be higher than gas pressure of the second chamber, to cause the dividing film to recess downwardly.

In an embodiment of the present disclosure, the imprinting method may further comprise: vacuumizing the second chamber.

In an embodiment of the present disclosure, the imprinting method may further comprise: causing gas pressure of the first chamber to be lower than gas pressure of the second chamber, to cause the dividing film to bulge upwardly.

In an embodiment of the present disclosure, when gas pressure of the first chamber is lower than gas pressure of the second chamber, the gas pressure of the first chamber may be in a range of 10⁻⁵ Pa to 1.01325×10⁵ Pa, and the gas pressure of second chamber may be in a range of 10⁻⁵ Pa to 1.01325×10⁵ Pa.

In an embodiment of the present disclosure, when gas pressure of the first chamber is lower than gas pressure of the second chamber, the gas pressure of the first chamber may be 10⁻³ Pa, and the gas pressure of second chamber may be 10⁻² Pa.

In an embodiment of the present disclosure, when gas pressure of the first chamber is higher than gas pressure of the second chamber, the gas pressure of the first chamber may be in a range of 1.01325×10⁵ Pa to 131.7225×10⁵ Pa, and the gas pressure of second chamber may be in a range of 10⁻⁵ Pa to 1.01325×10⁵ Pa.

In an embodiment of the present disclosure, when gas pressure of the first chamber is higher than gas pressure of the second chamber, the gas pressure of the first chamber may be 2×10⁵ Pa, and the gas pressure of second chamber may be 10⁻² Pa.

In an embodiment of the present disclosure, the imprinting stencil may be in contact with the substrate for 1 to 3600 seconds.

In an embodiment of the present disclosure, the imprinting stencil may be in contact with the substrate for 60 seconds.

In an embodiment of the present disclosure, the imprinting method may further comprise: placing the substrate to be imprinted in the second chamber, and placing the imprinting stencil on the movable supporting member.

In an embodiment of the present disclosure, the imprinting method may further comprise: combining the chamber body and the base via one or more sealing members.

The imprinting device and the imprinting method according to the present disclosure reduce a bubble-defect rate during imprinting process, while realizing uniform application of high pressure to a large area by a particular chamber design.

### BRIEF DESCRIPTION OF THE FIGURES

FIG. 1 is a schematic diagram illustrating a structure of an imprinting device according to an embodiment of the present disclosure;

FIG. 2 is a schematic diagram illustrating a pre-pressing stage using the imprinting device shown in FIG. 1;

FIG. 3 is a schematic diagram illustrating an imprinting stage using the imprinting device shown in FIG. 1; and

FIG. 4 is a flow chart of an imprinting method using an imprinting device according to an embodiment of the present disclosure.

### DETAILED DESCRIPTION

In order to provide a better understanding of the technical solutions of the present disclosure to those skilled in the art, an imprinting device and an imprinting method provided in the present disclosure will be described in further detail below in conjunction with the drawings.

FIG. 1 is a schematic diagram illustrating a structure of an imprinting device according to an embodiment of the present disclosure. As shown in FIG. 1, an imprinting device according to an embodiment of the present disclosure includes a chamber body 1 and a base 5 which are able to combine with each other to form an imprinting chamber. The imprinting chamber may be divided into a first chamber 2 and a second chamber 3 by a dividing film 7. The imprinting device may also include a movable supporting member, configured to support an imprinting stencil 8 inside the second chamber 3. The movable supporting member allows the imprinting stencil 8 to: under the drive of gas pressure within the imprinting chamber, contact a substrate 9 to be imprinted and apply a pressure to the substrate 9. It should be understood that, the chamber body 1 and the base 5 may be separated from each other before an imprinting process is performed, so that a substrate 9 to be imprinted can be placed on the base 5. After a substrate 9 to be imprinted is placed on the base 5, the chamber body 1 and the base 5 are able to combine with each other to form an imprinting chamber in which an imprinting process is performed on the substrate 9 to be imprinted. After the imprinting process is finished, the chamber body 1 and the base 5 may be separated from each other again, so that the imprinted substrate 9 is taken out and a new substrate 9 to be imprinted can be placed on the base 5.

The first chamber 2 may be located above the second chamber 3. When an imprinting process is performed, the substrate 9 to be imprinted may be placed in the second chamber 3, and the imprinting stencil 8 may be located between the dividing film 7 and the substrate 9.

The dividing film 7 may be configured to recess downwardly in a case where gas pressure of the first chamber 2 is higher than gas pressure of the second chamber 3. In this case, gas pressure of the second chamber 3 drives the imprinting stencil 8 to move towards the substrate 9, contact the substrate 9, and press the substrate 9 downwardly, to perform an imprinting process on the substrate 9.

The second chamber 3 may be configured to be capable of being vacuumized. When the second chamber 3 is in a vacuum state, if there is a bubble, then pressure inside the bubble is much greater than pressure outside the bubble, which causes the bubble to burst, thereby reducing a bubble defect rate during the imprinting process.

The dividing film 7 may also be configured to bulge upwardly in a case where gas pressure of the first chamber 2 is lower than gas pressure of the second chamber 3. Before performing the imprinting process, the imprinting stencil 8 and the substrate 9 may be accommodated in the second chamber 3 without contacting each other, by causing the dividing film 7 to bulge upwardly. After finishing the imprinting process, the imprinting stencil 8 and the substrate 9 may be separated, also by causing the dividing film 7 to bulge upwardly.

The dividing film 7 may include a transparent organic material, which makes ultraviolet light curing possible.

The imprinting device according to an embodiment of the present disclosure decreases bubble defect rate during imprinting process by dividing the imprinting chamber into two chambers and vacuumizing one of the chambers. Moreover, the imprinting device according to an embodiment of the present disclosure realizes uniform application of high gas pressure by a special chamber design. Thus, the imprinting device according to an embodiment of the present disclosure decreases bubble defect rate, improves uniformity of large area imprinting, and makes possible large area nano-imprinting technology.

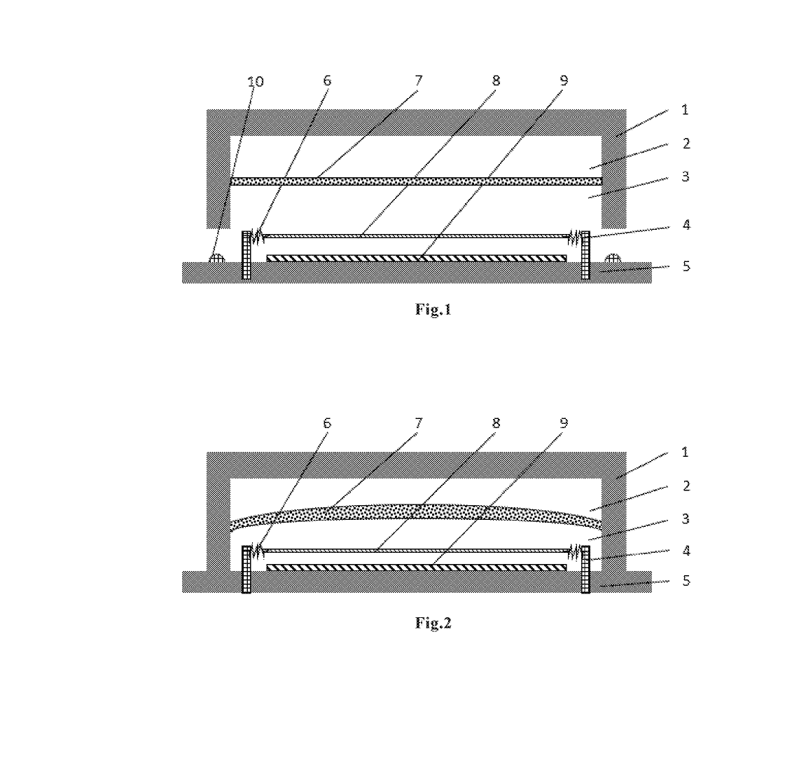

An imprinting process which may be performed using the imprinting device according to an embodiment of the present disclosure may include a pre-pressing stage and an imprinting stage. FIG. 2 is a schematic diagram illustrating a pre-pressing stage using the imprinting device shown in FIG. 1. In the pre-pressing stage, the second chamber 3 may be vacuumized. In this case, pressure inside a bubble is much greater than pressure outside the bubble, which causes the bubble to burst, thereby reducing a bubble defect rate during the imprinting process. In the pre-pressing stage, gas pressure of the first chamber 2 may be lower than gas pressure of the second chamber 3, to cause the dividing film 7 to bulge upwardly, thereby preventing the dividing film 7 from contacting the imprinting stencil 8, as shown in FIG. 2.

In the pre-pressing stage, gas pressure of the first chamber 2 may be in a range of 10⁻⁵ Pa to 1.01325×10⁵ Pa, and gas pressure of second chamber 3 may be in a range of 10⁻⁵ Pa to 1.01325×10⁵ Pa. For example, gas pressure of the first chamber 2 may be 10⁻³ Pa, and gas pressure of second chamber 3 may be 10⁻² Pa.

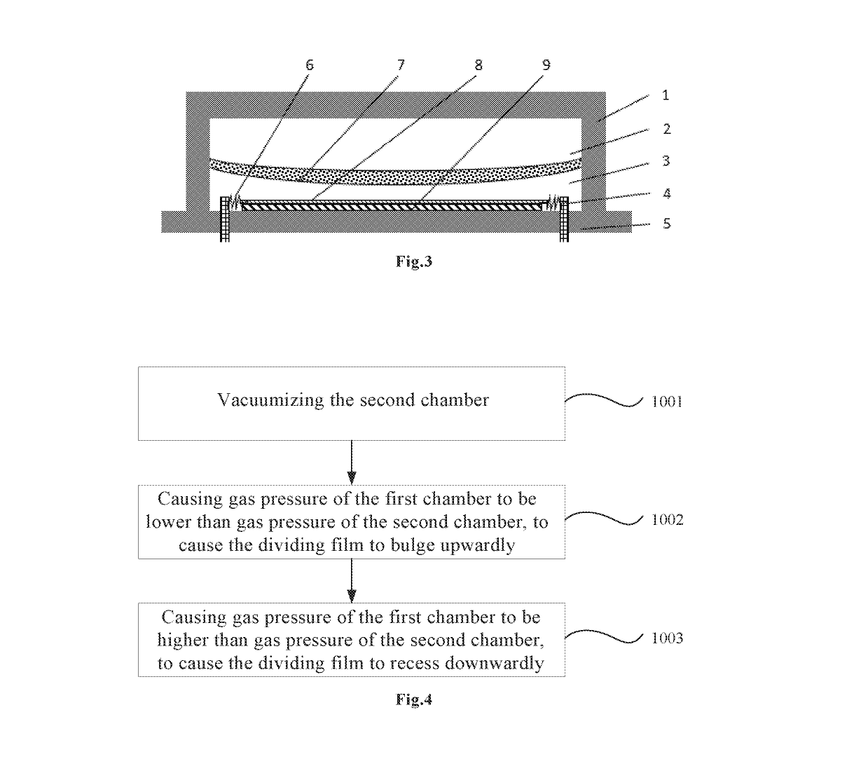

FIG. 3 is a schematic diagram illustrating an imprinting stage using the imprinting device shown in FIG. 1. In the imprinting stage, gas pressure of the first chamber 2 may be higher than gas pressure of the second chamber 3, to use high pressure of gas in the first chamber 2 to recess the dividing film 7 downwardly, as shown in FIG. 3. In this case, gas pressure of the second chamber 3 may drive the imprinting stencil 8 to move and contact the substrate 9, and apply uniform pressure to the substrate 9.

In the imprinting stage, gas pressure of the first chamber 2 may be in a range of 1.01325×10⁵ Pa to 131.7225×10⁵ Pa, and gas pressure of second chamber 3 may be in a range of 10⁻⁵ Pa to 1.01325×10⁵ Pa. For example, gas pressure of the first chamber 2 may be 2×10⁵ Pa, and gas pressure of second chamber 3 may be 10⁻² Pa.

Referring back to FIG. 1, the substrate 9 may be placed on the base 5. The movable supporting member may include a plurality of lifters 4 provided on the base 5. The lifters 4 may be arranged in peripheral regions of the substrate 9, and the imprinting stencil 8 may be connected to the lifters 4 via one or more elastic parts 6. Further, the chamber body 1 and the base 5 may be combined with each other via one or more sealing members 10.

When an imprinting process is performed, the imprinting stencil 8 may be in contact with the substrate 9 for 1 to 3600 seconds. For example, the imprinting stencil 8 may be in contact with the substrate 9 for 60 seconds.

FIG. 4 is a flow chart of an imprinting method using an imprinting device according to an embodiment of the present disclosure. The imprinting device may include a chamber body and a base which are able to combine with each other to form an imprinting chamber. The imprinting chamber may be divided into a first chamber and a second chamber by a dividing film. The imprinting device may also include a movable supporting member, configured to support an imprinting stencil inside the second chamber. The imprinting method may include a step of causing gas pressure within the imprinting chamber to drive the imprinting stencil, such that the imprinting stencil contacts a substrate to be imprinted and applies a pressure to the substrate to be imprinted.

In the imprinting method, the imprinting stencil may be controlled to contact the substrate for 1 to 3600 seconds. For example, the imprinting stencil may be in contact with the substrate for 60 seconds.

The imprinting device may be the imprinting device of FIG. 1. Before performing an imprinting, the substrate to be imprinted may be placed in the second chamber, and the imprinting stencil may be placed on the movable supporting member. For example, the substrate 9 may be placed on the base 5. For example, the imprinting stencil 8 may be connected to the lifters 4 by elastic parts 6. Further, the chamber body and the base may be combined with each other. For example, the chamber body 1 and the base 5 may be combined with each other via the sealing members 10.

The step of causing gas pressure within the imprinting chamber to drive the imprinting stencil may include Step 1003: causing gas pressure of the first chamber to be higher than gas pressure of the second chamber, to cause the dividing film to recess downwardly. In this step, gas pressure of the second chamber may drive the imprinting stencil to move and contact the substrate and apply uniform pressure to the substrate, to perform an imprinting process on the substrate. By this step, large area uniform imprinting may be realized.

In Step 1003, gas pressure of the first chamber may be in a range of 1.01325×10⁵ Pa to 131.7225×10⁵ Pa, and gas pressure of second chamber may be in a range of 10⁻⁵ Pa to 1.01325×10⁵ Pa. For example, gas pressure of the first chamber may be 2×10⁵ Pa, and gas pressure of second chamber may be 10⁻² Pa.

The imprinting method may also include Step 1001: vacuumizing the second chamber. By this step, bubbles may be caused to burst, thereby reducing bubble defect rate.

The imprinting method may also include Step 1002: causing gas pressure of the first chamber to be lower than gas pressure of the second chamber, to cause the dividing film to bulge upwardly. By this step, the dividing film may be prevented from contacting the imprinting stencil.

In Step 1002, gas pressure of the first chamber may be in a range of 10⁻⁵ Pa to 1.01325×10⁵ Pa, and gas pressure of second chamber may be in a range of 10⁻⁵ Pa to 1.01325×10⁵ Pa. For example, gas pressure of the first chamber may be 10⁻³ Pa, and gas pressure of second chamber may be 10⁻² Pa.

It can be understood that the foregoing implementations are merely exemplary implementations used for describing the principle of the present disclosure, but the present disclosure is not limited thereto. Those of ordinary skill in the art may make various variations and modifications without departing from the spirit and essence of the present disclosure, and these variations and modifications shall fall into the protection scope of the present disclosure.

1. An imprinting device, comprising:
a chamber body and a base, which are able to combine with each other to form an imprinting chamber, the imprinting chamber being divided into a first chamber and a second chamber by a dividing film; and
a movable supporting member, configured to support an imprinting stencil inside the second chamber, and to allow the imprinting stencil to: under the drive of gas pressure within the imprinting chamber, contact a substrate to be imprinted and apply a pressure to the substrate to be imprinted.

2. The imprinting device according to claim 1, wherein the dividing film is configured to recess downwardly in a case where gas pressure of the first chamber is higher than gas pressure of the second chamber.

3. The imprinting device according to claim 1, wherein the dividing film is configured to bulge upwardly in a case where gas pressure of the first chamber is lower than gas pressure of the second chamber.

4. The imprinting device according to claim 1, wherein the first chamber is located above the second chamber, the substrate to be imprinted is placed in the second chamber, and the imprinting stencil is located between the dividing film and the substrate to be imprinted.

5. The imprinting device according to claim 1, wherein the second chamber is configured to be capable of being vacuumized.

6. The imprinting device according to claim 1, wherein the substrate to be imprinted is placed on the base, the movable supporting member includes a plurality of lifters provided on the base, the lifters are arranged in peripheral regions of the substrate to be imprinted, and the imprinting stencil is connected to the lifters via one or more elastic parts.

7. The imprinting device according to claim 1, wherein the chamber body and the base are able to combine with each other via one or more sealing members.

8. The imprinting device according to claim 1, wherein the dividing film includes a transparent organic material.

9. An imprinting method using an imprinting device, wherein the imprinting device includes:
a chamber body and a base, which are able to combine with each other to form an imprinting chamber, the imprinting chamber being divided into a first chamber and a second chamber by a dividing film; and
a movable supporting member, configured to support an imprinting stencil inside the second chamber,
the imprinting method comprising:
a step of causing gas pressure within the imprinting chamber to drive the imprinting stencil, such that the imprinting stencil contacts a substrate to be imprinted and applies a pressure to the substrate to be imprinted.

10. The imprinting method according to claim 9, wherein the step of causing gas pressure within the imprinting chamber to drive the imprinting stencil includes: causing gas pressure of the first chamber to be higher than gas pressure of the second chamber, to cause the dividing film to recess downwardly.

11. The imprinting method according to claim 9, further comprising: vacuumizing the second chamber.

12. The imprinting method according to claim 9, further comprising: causing gas pressure of the first chamber to be lower than gas pressure of the second chamber, to cause the dividing film to bulge upwardly.

13. The imprinting method according to claim 12, wherein the gas pressure of the first chamber is in a range of 10⁻⁵ Pa to 1.01325×10⁵ Pa, and the gas pressure of second chamber is in a range of 10⁻⁵ Pa to 1.01325×10⁵ Pa.

14. The imprinting method according to claim 13, wherein the gas pressure of the first chamber is 10⁻³ Pa, and the gas pressure of second chamber is 10⁻² Pa.

15. The imprinting method according to claim 10, wherein the gas pressure of the first chamber is in a range of 1.01325×10⁵ Pa to 131.7225×10⁵ Pa, and the gas pressure of second chamber is in a range of 10⁻⁵ Pa to 1.01325×10⁵ Pa.

16. The imprinting method according to claim 15, wherein the gas pressure of the first chamber is 2×10⁵ Pa, and the gas pressure of second chamber is 10⁻² Pa.

17. The imprinting method according to claim 9, wherein the imprinting stencil is in contact with the substrate for 1 to 3600 seconds.

18. The imprinting method according to claim 17, wherein the imprinting stencil is in contact with the substrate for 60 seconds.

19. The imprinting method according to claim 9, further comprising: placing the substrate to be imprinted in the second chamber, and placing the imprinting stencil on the movable supporting member.

20. The imprinting method according to claim 9, further comprising: combining the chamber body and the base via one or more sealing members.
